(19) United States
(12) Patent Application Publication
(10) Pub. No.: US 2019/0369292 A1
(43) Pub. Date: Dec. 5, 2019

(54) ANTIREFLECTIVE POLARIZING PLATE, OPTICAL LAMINATE, AND METHOD FOR PRODUCING OPTICAL LAMINATE

(71) Applicant: Sumitomo Chemical Company, Limited, Tokyo (JP)

(72) Inventors: Yong-Won Seo, Pyeongtaek-si (KR); Byunghoon Song, Pyeongtaek-si (KR); Donghwi Kim, Pyeongtaek-si (KR)

(21) Appl. No.: 16/425,198

(22) Filed: May 29, 2019

(30) Foreign Application Priority Data
May 31, 2018 (JP) 2018-105219
Apr. 10, 2019 (JP) 2019-075029

(51) Int. Cl. G02B 1/111; G02B 5/30; H01L 51/52

(52) U.S. Cl. CPC G02B 1/111; H01L 27/323; H01L 51/5281; G02B 5/3016

(57) ABSTRACT

An antireflective polarizing plate which is disposed on a front surface of an image display panel and is capable of sufficiently restraining visibility deterioration caused by the reflection of external light is provided. The antireflective polarizing plate is disposed on a front surface of an image display panel having a front-surface reflectance of Rp (%), and has a luminosity corrected cross transmittance Tcr (%) satisfying a relation expressed by the following formula: Rp×Tcr≤150.

### BACKGROUND OF THE INVENTION

### Field of the Invention

The present invention relates to an antireflective polarizing plate, an optical laminate, and a method for producing an optical laminate.

### Description of the Related Art

Image display devices usually adopt a structure in which an antireflective polarizing plate is disposed on the viewing side of an image display panel to restrain visibility deterioration caused by the reflection of external light.

The antireflective polarizing plate may be constituted of a linear polarizing plate and a retardation plate having a ¼ wavelength retardation layer. JP-2012-133312 (Patent Document 1) discloses an antireflective polarizing plate constituted using a polarizing film having a thickness of 10 μm or less and high optical characteristics.

### SUMMARY OF THE INVENTION

It is an object of the present invention to provide an antireflective polarizing plate which is disposed on the front surface of an image display panel and can sufficiently restrain visibility deterioration caused by the reflection of external light, an optical laminate provided with the antireflective polarizing plate, and a method for producing the optical laminate.

The present invention provides an antireflective polarizing plate, an image display device provided with the antireflective polarizing plate, and a method for producing the image display device as shown below.

[1] An antireflective polarizing plate disposed on a front surface of an image display panel having a front-surface reflectance of Rp (%),

the antireflective polarizing plate having a luminosity corrected cross transmittance Tcr (%) satisfying a relation expressed by the formula (1a):

Rp×Tcr≤150 (1a)

[2] The antireflective polarizing plate according to the above [1];

the antireflective polarizing plate including a touch sensor panel, a retardation plate, and a linear polarizing plate in this order,

being disposed on the front surface of the image display panel such that the touch sensor panel faces the image display panel, and

having a luminosity corrected cross transmittance Tcr (%) satisfying a relation expressed by the formula (1d):

Rp×Tcr≤100 (1d)

[3] The antireflective polarizing plate according to the above [1] or [2],

the antireflective polarizing plate having a luminosity corrected transmittance Tcr (%) satisfying a relation expressed by the formula (1b):

Rp×Tcr≤68 (1b)

[4] The antireflective polarizing plate according to any one of the above [1] to [3],

the antireflective polarizing plate having a luminosity corrected degree of polarization Py (%) of 95% or more.

[5] The antireflective polarizing plate according to any one of the above [1] to [4],

the antireflective polarizing plate further including a polarizing layer containing a polymer of a polymerizable liquid crystal compound.

[6] An optical laminate including an image display panel and the antireflective polarizing plate according to any one of the above [1] to [5], the antireflective polarizing plate being disposed on the front surface of the image display panel.

[7] The optical laminate according to the above [6], the optical laminate being an organic EL display device.

[8] A method for producing an optical laminate, the method comprising:

a step of preparing an image display panel having a front-surface reflectance of Rp (%);

a step of preparing an antireflective polarizing plate having a luminosity corrected cross transmittance Tcr (%) satisfying a relation expressed by the formula (1a); and

a step of disposing the antireflective polarizing plate on the front surface of the image display panel:

Rp×Tcr≤150 (1a)

The visibility deterioration caused by the reflection of external light on the front surface of the image display panel can be sufficiently restrained by using the antireflective polarizing plate of the present invention.

### BRIEF DESCRIPTION OF THE DRAWINGS

FIG. 1 is a vertical sectional view showing an example of an organic EL display device;

FIG. 2 is a vertical sectional view showing another example of an organic EL display device;

FIG. 3 is a view showing the layer structure of a pixel of an organic EL display device and its driving circuit;

FIG. 4 is a vertical sectional view of a sample of a verification optical laminate; and

FIG. 5 is a vertical sectional view of a sample of a verification optical laminate.

### DETAILED DESCRIPTION OF THE PREFERRED EMBODIMENTS

An antireflective polarizing plate in an embodiment of the present invention, an optical laminate provided with the antireflective polarizing plate and an image display panel, and a method for producing the optical laminate will be explained hereinbelow. The optical laminate can constitute an image display device either singly or by combining other structural elements.

### (Antireflective Polarizing Plate)

The antireflective polarizing plate of this embodiment is provided with a linear polarizing plate and a retardation plate and disposed on the front surface of an image display panel having a front-surface reflectance of Rp (%). In other words, the antireflective polarizing plate of this embodiment is disposed on the viewing side of the image display panel having a reflectance of Rp (%) measured when observed from the viewing side. The antireflective polarizing plate is arranged such that the retardation plate and linear polarizing plate are positioned in this order from the side closer to the front surface of the image display panel. The antireflective polarizing plate may have a structure which is further provided with a touch sensor panel and is arranged such that the touch sensor panel, retardation plate, and linear polarizing plate are positioned in this order from the side closer to the front surface of the image display panel.

The antireflective polarizing plate has a luminosity corrected cross transmittance Tcr (%) satisfying the relation expressed by the formula (1a) and preferably the formula (1b):

Rp×Tcr≤150 (1a)

Rp×Tcr≤68 (1b)

When the antireflective polarizing plate satisfies the relation expressed by the formula (1a), visibility deterioration caused by the reflection of external light can be sufficiently restrained in an image display device. Also, when the antireflective polarizing plate satisfies the relation expressed by the formula (1b), visibility deterioration caused by the reflection of external light can be more restrained in an image display device. In this case, the reflectance Rp (%) is defined as a value measured in an SCI (including specular reflection light) mode by using a spectrophotometer (CM-2600d, manufactured by KONICA MINOLTA, INC.). The reflectance Rp (%) is a luminous reflectance, that is, a Y-value (%) among tristimulus values in the XYZ color specification system and can be measured according to JIS Z 8722.

The antireflective polarizing plate has a luminosity corrected cross transmittance Tcr (%) satisfying the relation expressed by, preferably, the formula (1d) and more preferably, the formula (1b) when it is structurally so arranged that the touch sensor panel, retardation plate, and linear polarizing plate are positioned in this order from the side closer to the front surface of the image display panel:

Rp×Tcr≤100 (1d)

When the antireflective polarizing plate is provided with the touch sensor panel, the antireflective polarizing plate produces an effect that makes invisible the conductive layer of the touch sensor panel if it satisfies the relation expressed by the formula (1d).

The reflectance Rp (%) of the image display panel is, for example, 10% or more and 99% or less. The reflectance Rp (%) of the image display panel can be controlled, for example, by the materials of an anode electrode and cathode electrode as will be mentioned later. The antireflective polarizing plate preferably has a luminosity corrected cross transmittance Tcr (%) satisfying the relation expressed by the formula (1c) from the viewpoint of more intensifying the emission of the panel than reflected external light to thereby improve the visibility of the screen in an image display device:

1≤Rp×Tcr (1c)

The luminosity corrected cross transmittance Tcr (%) of the antireflective polarizing plate is preferably 0.1% or more and 10% or less, and more preferably 0.2% or more and 5% or less from the viewpoint of obtaining high screen brightness while restraining visibility deterioration caused by external light in an image display device. The luminosity corrected cross transmittance Tcr (%) of the antireflective polarizing plate can be controlled by, for example, the luminosity corrected cross transmittance of the linear polarizing plate, the retardation value and wavelength dispersion of the retardation plate, and the layer structure of the touch sensor panel.

The luminosity corrected unit transmittance Ty (%) of the antireflective polarizing plate is preferably 40% or more and 48% or less, and more preferably 41% or more and 47% or less from the viewpoint of obtaining high screen brightness while restraining visibility deterioration caused by external light in an image display device. Also, the luminosity corrected degree of polarization Py (%) of the antireflective polarizing plate is preferably 92% or more and 99.9% or less, and more preferably 95% or more and 99.8% or less from the viewpoint of obtaining high screen brightness while restraining visibility deterioration caused by external light in an image display device.

The luminosity corrected cross transmittance Tcr (%) and luminosity corrected degree of polarization Py (%) of the antireflective polarizing plate satisfy the relation expressed by, preferably, the formula (2a) and more preferably, the formula (2b):

Rp×Tcr×Py≤1.5×10⁴ (2a)

Rp×Tcr×Py≤6.5×10³ (2b)

The antireflective polarizing plate preferably has a luminosity corrected cross transmittance Tcr (%) and luminosity corrected degree of polarization Py (%) which satisfy the relation expressed by the formula (2c) from the viewpoint of more intensifying the emission of the panel than reflected external light to thereby improve the visibility of the screen in an image display device:

1.0×10³≤Rp×Tcr×Py (2c)

The thickness of the antireflective polarizing plate is preferably 50 to 500 μm, more preferably 50 to 200 μm, and even more preferably 50 to 150 μm from the viewpoint of making a thinner polarizing plate.

The antireflective polarizing plate is provided with the linear polarizing plate and retardation plate and can be obtained, for example, by laminating the both with a pasting layer such as an adhesive layer interposed therebetween. The linear polarizing plate and retardation plate constituting the antireflective polarizing plate may be each a single layer or multilayer.

In the antireflective polarizing plate, the retardation plate and linear polarizing plate are preferably laminated such that the slow axis (optical axis) of the retardation plate forms an angle of, substantially, 45° or 135° with the absorption axis of the linear polarizing plate. An antireflective function can be obtained by laminating both plates in such a manner that the slow axis (optical axis) of the retardation plate forms an angle of, substantially, 45° or 135° with the absorption axis of the linear polarizing plate. In this case, the description “substantially, 45° or 135°” is usually a value falling in a range of 45±5° or 135±5°.

The luminosity corrected cross transmittance Tcr (%), luminosity corrected unit transmittance Ty (%), and luminosity corrected degree of polarization Py (%) of the antireflective polarizing plate in this specification are values obtained by measurement and calculation according to the following methods. MD transmittance and TD transmittance of each antireflective polarizing plate are measured at a wavelength range from 380 to 780 nm by using an integrating sphere spectrophotometer (V7100, manufactured by JASCO Corporation) to calculate single transmittance and degree of polarization at each wavelength based on the following formulae:

Single transmittance(%)=(MD+TD)/2

Degree of Polarization(%)={(MD−TD)/(MD+TD)}×100

“MD transmittance” is a transmittance obtained when the direction of polarization of light emitted from a Glan-Thomson prism is made to be parallel to the transmission axis of the linear polarizing plate of the antireflective polarizing plate and is expressed by “MD” in the above formulae. Also, “TD transmittance” is a transmittance obtained when the direction of polarization of light emitted from a Glan-Thomson prism is made to be perpendicular to the transmission axis of the linear polarizing plate of the antireflective polarizing plate and is expressed by “TD” in the above formulae. Luminosity correction is made for the obtained single transmittance, degree of polarization, and cross transmittance (TD transmittance) using a 2-degree field of view (C-light source) in JIS 28701: 1999 “Color display method-XYZ colorimetric system and X₁₀Y₁₀Z₁₀ colorimetric system” to calculate the luminosity corrected unit transmittance (Ty), luminosity corrected degree of polarization (Py), and luminosity corrected cross transmittance (Tcr).

### <Retardation Plate>

The retardation plate is used together with a linear polarizing plate and has a function of converting linearly polarized light from the linear polarizing plate into circularly polarized light (right or left-handed circularly polarized light) by phase difference and converting the circularly polarized light (right or left-handed circularly polarized light) reflected by an image display panel again into linearly polarized light (at this time, the direction of oscillation of the linearly polarized light accords with the absorption axis of the polarizing plate. The circularly polarized light so called here includes elliptically polarized light within the extent that it develops an antireflective function.

The retardation plate includes a retardation layer which is typically a ¼ wavelength retardation layer. This ¼ wavelength retardation layer preferably has a Re (550), which is a plane retardation value at a wavelength of 550 nm, satisfying the relation expressed by the following formula: 100 nm≤Re (550)≤160 nm, and more preferably has a Re (550) satisfying the relation expressed by the following formula: 110 nm≤Re (550)≤150 nm.

With regards to the wavelength dispersibility of the retardation layer, any retardation layer having a wide range of wavelength dispersibility ranging from positive dispersibility to reverse dispersibility can be widely used insofar as it substantially develops a wavelength dispersion function. Particularly, a retardation layer having reverse dispersibility is preferable because it can develop an antireflective function without depending on wavelength. Specifically, the retardation layer preferably satisfies the relation expressed by the following formula: Re (450)≤Re (550)≤Re (650) and more preferably satisfies the relation expressed by the following formula: Re (450)<Re (550)<Re (650).

The ¼ wavelength retardation layer has a retardation Rth (550) of, preferably, −120 to 120 nm and more preferably −80 to 80 nm wherein the R(th) is a retardation value in the direction of thickness measured at a wavelength of 550 nm.

The retardation plate is not limited to those having a ¼ wavelength retardation layer and may be those having, for example, a ⅕ wavelength retardation layer or ⅙ wavelength retardation layer insofar as they are capable of substantially developing an antireflective function when the antireflective polarizing plate is formed. The retardation plate provided with a ¼ wavelength retardation layer is also called “a ¼ wavelength plate” hereinbelow. The retardation plate may be provided with a positive C layer as the retardation layer.

Examples of the retardation plate include those obtained by supporting a liquid crystal layer containing a polymer of a polymerizable liquid crystal compound (or those obtained by peeling the support film thereafter) and orientation films obtained by orienting a polymer material uniaxially or biaxially.

The optical characteristics of the liquid crystal layer containing a polymer of a polymerizable liquid crystal compound can be controlled by the oriented state of the polymerizable liquid crystal compound. Examples of the polymerizable liquid crystal compound include rod-like polymerizable liquid crystal compounds and disk-shaped polymerizable liquid crystal compounds. The direction of the optical axis of the oriented layer formed by orienting a rod-like polymerizable liquid crystal compound horizontally or vertically with a base material accords with the direction of the longitudinal direction of the polymerizable liquid crystal compound. The optical axis of the oriented layer formed by orienting a disk-shaped polymerizable liquid crystal compound exists along with a direction perpendicular to the disk surface of the polymerizable liquid crystal compound.

It is only required to orient the polymerizable liquid crystal compound in an appropriate direction in order that the liquid crystal layer formed by polymerizing the polymerizable liquid crystal compound develops plane retardation. When the polymerizable liquid crystal compound is a rod-like compound, plane retardation is developed by orienting the optical axis of the polymerizable liquid crystal compound horizontally with the base material plane. In this case, the optical axis direction accords with the slow axis direction. When the polymerizable liquid crystal compound is a disk-like compound, plane retardation is developed by orienting the optical axis of the polymerizable liquid crystal compound horizontally with the base material plane. In this case, the optical axis direction is perpendicular to the slow axis direction. The state of orientation of the polymerizable liquid crystal compound can be controlled by a combination of an orientation membrane and a polymerizable liquid crystal compound.

The polymerizable liquid crystal compounds are compounds which have polymerizable groups and are liquid-crystalline compounds. The polymerizable group means a group participating in polymerization reaction and is preferably a photopolymerizable group. Here, the photopolymerizable group means a group capable of participating in polymerization reaction by the aid of an active radical or acid generated from a photoinitiator which will be described later. Examples of the polymerizable group include a vinyl group, vinyloxy group, 1-chlorovinyl group, isopropenyl group, 4-vinylphenyl group, acryloyloxy group, methacryloyloxy group, oxiranyl group, and oxetanyl group. Among these groups, an acryloyloxy group, methacryloyloxy group, vinyloxy group, oxiranyl group, and oxetanyl group are desirable, and an acryloyloxy group is more desirable. With regards to the liquid crystallinity of the polymerizable liquid crystal, the polymerizable liquid crystal may be either a thermotropic liquid crystal or lyotropic liquid crystal or may be either a nematic liquid crystal or smectic liquid crystal when the thermotropic liquid crystals are classified by a degree of alignment order.

Examples of the polymerizable liquid crystal compound include compounds having a polymerizable group among the compounds described in Handbook of Liquid Crystals (edited by Liquid Crystal Handbook Editorial Committee, Maruzen Co., Ltd., published on Oct. 30, 2000) “3.8.6 Network (Fully Crosslinked Type)”, “6.5.1 Liquid Crystal Material b. Polymerizable Nematic Liquid Crystal Material” and polymerizable liquid crystal compounds described in JP-A-2002-267838, JP-A-2005-208415, JP-A-2005-208416, JP-A-2005-208414, JP-A-2006-052001, JP-A-2010-270108, JP-A-2010-31223, JP-A-2011-6360, JP-A-2011-207765, JP-T-2010-522893, JP-T-2011-207765, U.S. Pat. Nos. 6,139,771, 6,203,724, and 5,567,349.

The liquid crystal layer formed by polymerizing a polymerizable liquid crystal compound is usually formed by applying a composition (hereinafter also referred to as “coating liquid crystal composition”) having one or more polymerizable compounds to the surface of a base material, orientation membrane, or protection layer and by polymerizing the polymerizable liquid crystal compound contained in the obtained coating film.

The coating liquid crystal composition usually contains a solvent. As the solvent, a solvent which can dissolve the polymerizable liquid crystal compound and is inert to a polymerization reaction of the polymerizable liquid crystal compound is preferable.

The content of the solvent in the coating liquid crystal composition is preferably 10 parts by mass to 10000 parts by mass and more preferably 50 parts by mass to 5000 parts by mass based on 100 parts by mass of solid content. The solid content means the sum of components excluding the solvent from the coating liquid crystal composition.

Coating of the coating liquid crystal composition is performed by known methods including coating methods such as a spin coating method, extrusion method, gravure coating method, die coating method, slit coating method, bar coating method, and applicator method and printing methods such as a flexographic method. After the coating is finished, the solvent is usually removed under the condition that does not allow the polymerization of the polymerizable liquid crystal compound contained in the obtained coating film to thereby form a dry coating film. Examples of the drying method include a natural drying method, draught drying method, heating drying method, and vacuum drying method.

The base material is usually a transparent base material. The transparent base material means a base material having transparency that allows the transmission of light and especially, visible light, and the transparency means the characteristics that the transmittance of beams having a wavelength range from 380 to 780 nm is 80% or more. Examples of the resin constituting the transparent base material include polyolefins such as polyethylene and polypropylene; cyclic olefin type resins such as norbornane type polymers; polyvinyl alcohols; polyethylene terephthalates; polymethacrylates; polyacrylates; cellulose esters such as triacetyl cellulose, diacetyl cellulose, and cellulose acetate propionate; polyethylene naphthalates; polycarbonates; polysulfones; polyether sulfones; polyether ketones; polyphenylene sulfides, and polyphenylene oxides. Polyethylene terephthalates, polymethacrylates, cellulose esters, cyclic olefin type resins, or polycarbonates are preferable from the viewpoint of availability and transparency.

The orientation membrane is one having orientation regulation force that makes the polymerizable liquid crystal compound undergo liquid crystal orientation in a desired direction.

The orientation membrane is preferably those which have solvent resistance to prevent the film from being dissolved caused by, for example, application of the coating liquid crystal composition and heat resistance in heat treatment performed to remove solvents and to align the polymerizable liquid crystal. Examples of the orientation membrane include orientation membranes containing orientation polymers and photo-orientation membranes and these films may be obtained by applying an orientation polymer forming composition or photo-orientation membrane forming composition to a base material.

Examples of a method used to apply an orientation polymer forming composition or photo-orientation membrane forming composition to a base material include known methods, for example, coating methods such as a spin coating method, extrusion method, gravure coating method, die coating method, slit coating method, bar coating method, and applicator method and printing methods such as a flexographic method. When this optical film is manufactured by a roll to roll system continuous production method which will be described later, a gravure coating method, die coating method, or printing method such as a flexographic method is usually adopted as the coating method.

The thickness of the orientation membrane is usually in a range from 10 nm to 10000 nm, preferably in a range from 10 nm to 1000 nm, more preferably 500 nm or less, and even more preferably in a range from 10 nm to 500 nm.

The polymerization of the polymerizable liquid crystal compound may be performed by a known method used to polymerize a compound having a polymerizable group. Specifically, thermal polymerization and photopolymerization are exemplified as the method, the photopolymerization being desirable from the viewpoint of polymerization easiness. When the polymerizable liquid crystal is polymerized by photopolymerization, it is preferable that the polymerizable liquid crystal compound be put into the liquid crystal phase state in the dried coating film obtained by applying the polymerizable liquid crystal composition containing a photoinitiator and drying and then made to undergo photopolymerization with keeping the polymerizable liquid crystal compound in the liquid crystal state.

The retardation layer contained in the retardation plate is a liquid crystal layer obtained in the above manner. The retardation plate may be a laminate having the layer structure “base material/orientation membrane/liquid crystal layer” obtained in the above manner, a laminate having a layer structure “orientation membrane/liquid crystal layer” obtained by peeling the base material, a retardation plate consisting only of a liquid crystal layer left after peeling the base material and orientation membrane, or a retardation plate prepared by further laminating other layers on a laminate having a layer structure “base material/orientation membrane/liquid crystal layer”.

When the retardation layer is an orientation film, it is preferable to form the orientation film by producing a film by a solution film forming method or extrusion molding method and by orienting the obtained film. Examples of the orientation method include longitudinal uniaxial orientation that is a method of orienting in a machine flow direction; transversal uniaxial orientation that is a method of orienting in a direction transverse to a machine flow direction; biaxial orientation that is a method of performing longitudinal orientation and transversal orientation simultaneously; and diagonal orientation.

There is no particular limitation to the material of the film and specifically, materials having a positive or negative inherent birefringence value or combinations of materials having a positive or negative value may be used to produce a film. The aforementioned “material having a positive inherent birefringence value” means a material that optically exhibits positive uniaxiality in the case where molecules are oriented with uniaxially orientation order. This means that in the case of, for example, a raw resin having a positive inherent birefringence value, the light reflectance in the orientation direction of molecules is larger than that in a direction perpendicular to the above orientation direction.

The aforementioned “material having a negative inherent birefringence value” means a material that optically exhibits negative uniaxiality in the case where molecules are oriented with uniaxially orientation order.

This means that in the case of, for example, a raw resin having a negative inherent birefringence value, the light reflectance in the orientation direction of molecules is smaller than that in a direction perpendicular to the above orientation direction.

Examples of the film material include polyolefins such as polyethylene and polypropylene; cyclic olefin type resins such as norbornane type polymers; polyvinyl alcohols; polyethylene terephthalates; polymethacrylates; polyacrylates; cellulose esters such as triacetyl cellulose, diacetyl cellulose, and cellulose acetate propionate; polyethylene naphthalates; polycarbonates; polysulfones; polyether sulfones; polyether ketones; polyphenylene sulfides, and polyphenylene oxides.

The thickness of the retardation layer is usually 10 μm or less, preferably 5 μm or less, more preferably 0.5 μm or more and 5 μm or less when the retardation layer is a liquid crystal layer. The thickness of the retardation layer is usually 100 μm or less, preferably 60 μm or less, more preferably 5 μm or more and 50 μm or less when the retardation layer is an orientation film.

### <Linear Polarizing Plate>

The linear polarizing plate serves as a member that converts natural light (external light) incident thereto from the outside into linearly polarized light and cuts the light reflected from an image display panel to thereby reduce the reflection of external light. Examples of the linear polarizing plate include linear polarizing plates (hereinafter also referred to as “PVA polarizing plates”) each obtained by protecting one or both surfaces of a PVA polarizing layer in which a dichroic pigment such as iodine or a dichroic dye is adsorbed to and oriented on a uniaxially oriented polyvinyl alcohol resin film (PVA), with a polymer film (protection film). In this case, for example, a transparent resin film is used as the protection film. Examples of the transparent resin include acetyl cellulose type resins represented by triacetyl cellulose and diacetyl cellulose, methacrylic resins represented by polymethylmethacrylate, polyester resins, polyolefin type resins, polycarbonate resins, polyether ether ketone resins, and polysulfone resins. The thickness of the PVA polarizing layer is, for example, 1 to 100 μm and preferably 5 to 50 μm.

Examples of the linear polarizing plate include linear polarizing plates (hereinafter also referred to as “liquid crystal type polarizing plates”) provided with a polarizing layer containing a polymer of a polymerizable liquid crystal compound and a dichroic dye. As the liquid crystal type polarizing plate, those exemplified in, for example, JP-A-2012-58381, JP-A-2013-37115, WO2012/147633, and WO2014/091921 may be used.

The polarizing layer containing a polymer of a polymerizable liquid crystal compound and a dichroic dye may be used as a polarizing plate either independently or in the form of a structure in which a protection film is formed on one or both surfaces of the polarizing layer. As the protection film, the same one as the protection film used in the linear polarizing plate of the above PVA polarizing layer may be used.

The liquid crystal layer of the liquid crystal type polarizing plate has a thickness of, usually, 20 μm or less, preferably 5 μm or less, and more preferably 0.1 μm or more and 3 μm or less because if the thickness is excessively thin, the liquid crystal layer tends to be reduced in strength and deteriorated in processability, though the liquid crystal layer is preferably thin from the viewpoint of developing a thinner membrane.

### <Touch Sensor Panel>

As the touch sensor panel, any sensor capable of detecting the position to be touched may be used without any particular limitation to the detection system and, for example, resistive membrane type, capacitance coupling type, photosensor type, ultrasonic type, electromagnetic induction coupling type, or ultrasonic surface acoustic wave type touch sensor panels are exemplified. Resistive membrane type or capacitance coupling type touch sensor panels are preferably used in view of low cost.

An example of a resistive film type touch sensor panel has a structure including a pair of substrates disposed facing each other, an insulation spacer sandwiched between the pair of substrates, a transparent conductive membrane formed as a resistive membrane on the entire surface of the inside of each substrate, and a touch position detection circuit. In the image display device with the resistive membrane type touch sensor panel, a short circuit is developed between resistive membranes facing each other and current flows across the resistive membranes when the surface of the image display device is touched. The touch position detection circuit detects a voltage change to thereby detect a touch position.

An example of the capacitance coupling type touch sensor panel has a structure including a substrate, a position detection electrode formed on the entire surface of the substrate, and a touch position detection circuit. In an image display device with the capacitance coupling type touch sensor, the electrode is grounded at the touched point through the capacitance of a human body when the surface of the image display device is touched. The touch position detection circuit detects that the transparent electrode is grounded, to detect a touch position.

The capacitance coupling type touch sensor panel may be constituted only of a touch sensor pattern layer containing conductive layers such as electrodes and wiring (hereinafter also referred to as “touch sensor panel with non-base layer”) or may be provided with the touch sensor pattern layer and a base material layer supporting the touch sensor pattern layer (hereinafter also referred to as “touch sensor panel with a base material”. When the touch sensor panel is provided with the touch sensor pattern layer and base material layer, the both layers may be pasted by a pasting layer or the touch sensor pattern layer may be formed on the base material layer without interposing a pasting layer therebetween. The pasting layer is a pressure-sensitive adhesive layer or an adhesive layer, which may be formed using the above pressure-sensitive adhesive composition or adhesive composition.

The touch sensor pattern layer is preferably formed not to be visually recognized. The touch sensor pattern layer may include a release layer. The release layer may be formed on a substrate such as a glass substrate as a member that is released from the substrate together with the touch sensor pattern layer formed thereon. The release layer is preferably an inorganic material layer or organic material layer. Examples of material for forming the inorganic material layer include silicon oxide. Examples of material for forming the organic material layer include a (meth)acrylic resin composition, epoxy type resin composition, and polyimide type resin composition. The touch sensor pattern layer may further contain at least one protection layer. The protection layer may be provided to support a conductive layer in close contact with the conductive layer. The protection layer may contain at least one of an organic insulation membrane and inorganic insulation membrane and these membranes may be formed by a spin coating method, sputtering method, vapor deposition method, or the like. The conductive layer may be either a transparent conductive layer made from a metal oxide such as ITO or a metal layer made from a metal such as copper, silver, and gold. Also, the touch sensor pattern layer may be constituted only of a conductive layer such as an electrode and wiring. The base material layer is preferably a resin film, and as the resin film, a polyester type resin film such as a cyclic olefin type resin film and polyethylene terephthalate type resin film, acrylic resin film, triacetyl cellulose type resin film, or the like may be used.

### <Pasting Layer>

In an embodiment of the antireflective polarizing plate of the present invention, the pasting layer may be formed from a pressure-sensitive adhesive, water-based adhesive, and active energy ray curable adhesive or combinations of these compounds without any particular limitation to the kind of material in the case where the polarizing plate includes the pasting layer used to paste the retardation plate with the linear polarizing plate, in the case where the polarizing plate includes the pasting layer used to paste the retardation plate with the touch sensor panel, and in the case where the polarizing plate includes the pasting layer used to paste each layer in the touch sensor panel. The thickness of the pasting layer is preferably 0.1 μm to 50 μm, more preferably 0.1 μm to 10 μm, and even more preferably 0.5 μm to 5 μm.

### <Other Layer Structures>

The antireflective polarizing plate may have any of the structures of conventional and general elliptic polarizing plates, linear polarizing plates, and retardation plates. Examples of these structures include a pressure-sensitive adhesive (sheet) for pasting the antireflective polarizing plate to the image display panel, protection film used for the purpose of protecting the surface of a linear polarizing plate or retardation plate from damages and stains, and optical compensation layer such as a C-plate.

### <Application>

The antireflective polarizing plate may be used as a polarizing plate which is located on the front surface (viewing side) of an image display panel to provide an antireflective function and as a structural element in various optical laminates and image display devices. The optical laminate is provided with an image display panel and an antireflective polarizing plate disposed on the front surface of the image display panel. The image display device is provided with an image display panel, an antireflective polarizing plate disposed on the front surface of the image display panel, and, a light emitting element or light emitting device as a light emitting source. Examples of the image display device include liquid crystal display devices, organic electroluminescence (EL) display devices, inorganic electroluminescence (EL) display devices, touch panel display devices, electron-emission display devices (for example, a field-emission display device (FED) and surface field-emission display device (SED)), electronic papers (display devices using an electronic ink or electrophoretic element), plasma display devices, projection type display devices (for example, grating light valve (GLV) display device and display device containing a digital micromirror device (DMD)), and piezoelectric ceramic displays. These image display devices may be image display devices that display a two-dimensional image or stereoscopic image display devices that display a three-dimensional image.

### (Optical Laminate)

An embodiment of the optical laminate is provided with an image display panel and an antireflective polarizing plate disposed on the front surface (viewing side) of an image display panel.

The method for producing an optical laminate includes a step of preparing an image display panel having a front surface reflectance of Rp (%), a step of preparing an antireflective polarizing plate having a luminosity corrected cross transmittance Tcr (%) satisfying the formula (1a) and preferably the formula (1b), and a step of disposing the antireflective polarizing plate on the front surface of the image display panel. According to the method for producing an optical laminate in this embodiment, visibility deterioration caused by the reflection of external light can be sufficiently restrained in the optical laminate by selecting the antireflective polarizing plate corresponding to the front surface reflectance Rp (%) of the image display panel. In another embodiment, the image display panel may be selected such that it satisfies the formula (1a) corresponding to the luminosity corrected cross transmittance Tcr (%) of the antireflective polarizing plate.

The reflectance Rd (%) of the front surface (surface on the side provided with the antireflective polarizing plate) of the optical laminate is preferably 6.1% or less and more preferably 5.0% or less from the viewpoint of restraining visibility deterioration caused by the reflection of external light. In this case, the reflectance Rd (%) is a value measured in an SCI mode by using a spectrophotometer (CM-2600d, manufactured by KONIKA MINOLTA INC.).

### <Organic EL Display Device>

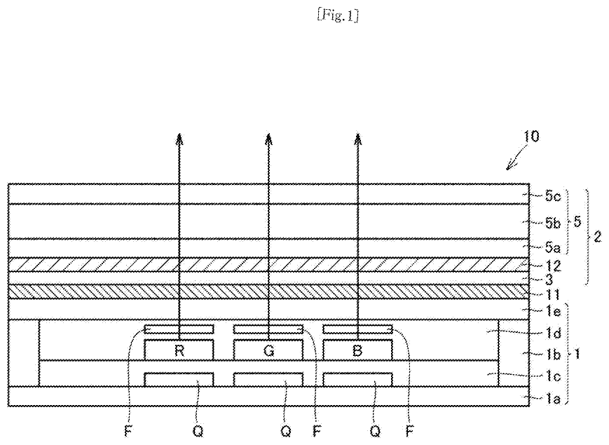

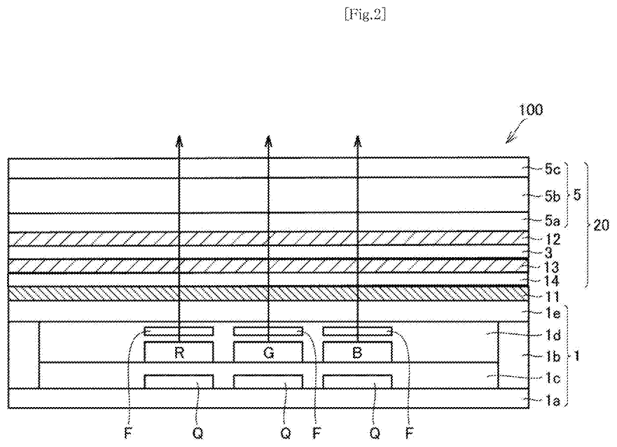

An organic EL display device in one embodiment of the optical laminate will be explained in detail with reference to the drawings. The same signs are used for the same structural elements and duplicated explanations are omitted. FIG. 1 is a vertical sectional view showing an embodiment of the organic EL display device of the present invention and FIG. 2 is a vertical sectional view showing another embodiment of the organic EL display device of the present invention. The organic EL display device is an optical laminate according to the present invention and is also, an image display device according to the present invention.

An organic EL display device 10 shown in FIG. 1 is provided with an organic EL panel 1 that is an image display panel and an antireflective polarizing plate 2 stuck to the surface of the organic EL panel 1 through a first pressure-sensitive adhesive 11. The antireflective polarizing plate 2 is provided with a ¼ wavelength plate 3 and a linear polarizing plate 5 stuck to the surface of the ¼ wavelength plate 3 through a second pressure-sensitive adhesive 12.

The organic EL panel 1 is provided with a support substrate 1a made from glass or the like, a frame spacer 1b formed along the outside periphery of the support substrate 1a, and a seal substrate 1e which supports the frame spacer 1b between the seal substrate and the support substrate 1a, wherein the space between both substrates is sealed and a plurality of light emitting elements are disposed in the space.

A plurality of thin-film transistors Q is formed in the form of matrix on the support substrate 1a and RGB organic light emitting diodes are disposed through a coating layer 1c that coats the thin-film transistor Q in each pixel. The RGB organic light emitting diodes are light emitting diodes with an organic light emitting layer and can emit lights having various wavelengths. In this embodiment, red, green, and blue color filters F are formed between the RGB organic light emitting diodes and seal substrate 1e but these filters are not always necessary.

There is a space 1d in which gas is sealed between the coating layer 1c and seal substrate 1e and the space 1d may be filled with a resin or the like.

The first pressure-sensitive adhesive 11 is applied to or laminated on the seal substrate 1e and serves as a member that sticks the ¼ wavelength plate 3 to the surface of the seal substrate 1e. The second pressure-sensitive adhesive 12 is applied to or laminated on the surface of the ¼ wavelength plate 3 and serves as a member that sticks the linear polarizing plate 5 to the surface of the ¼ wavelength plate 3. The linear polarizing plate 5 includes a polarizing layer 5b, a first transparent protection film 5a and a second transparent protection film 5c provided on both sides of the polarizing layer 5b.

Upon emission of light from the RGB organic light emitting diodes, the light is output to the outside through the filter F, seal substrate 1e, first pressure-sensitive adhesive 11, ¼ wavelength plate 3, second pressure-sensitive adhesive 12, and linear polarizing plate 5 sequentially.

Also, external light is reflected at various places in the organic EL display device and then reflected to the outside. Particularly, because electrodes positioned on the surface of the RGB organic light emitting diodes have high reflectance, the electrodes exert a large influence on the above reflection.

The organic EL display device 100 shown in FIG. 2 is provided with an organic EL panel 1 that is an image display panel and an antireflective polarizing plate 20 stuck to the surface of the organic EL panel 1 through a first pressure-sensitive adhesive 11. The antireflective polarizing plate 20 is provided with a ¼ wavelength plate 3 and a linear polarizing plate 5 stuck to the ¼ wavelength plate 3 through a second pressure-sensitive adhesive 12, and is further provided with a touch sensor panel 14 laminated on the surface of the ¼ wavelength plate 3 on the side opposite to the linear polarizing plate 5 through a third pressure-sensitive adhesive 13. The organic EL display device 100 shown in FIG. 2 is different from the organic EL display device 10 shown in FIG. 1 only in the point that it is provided with the touch sensor panel 14 through the third pressure-sensitive adhesive 13 in the antireflective polarizing plate 20. When the touch sensor panel 14 is a touch sensor panel with a base material, it is preferable that the base material be arranged on the organic EL panel 1 side and the touch sensor pattern layer is arranged on the viewing side.

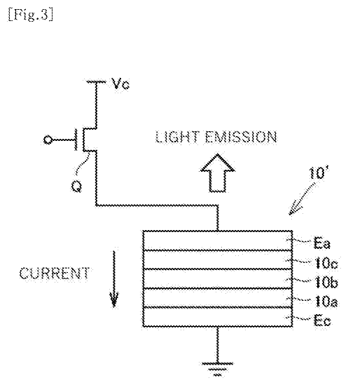

FIG. 3 is a view showing the layer structure of the organic light emitting diode and its driving circuit. A typical one of the above RGB organic light emitting diodes is shown by a sign 10′.

The light emitting diode 10′ is provided with a cathode electrode Ec, an electron transport layer 10a formed on the cathode electrode Ec, a light emitting layer 10b, a hole transport layer 10c, and an anode electrode Ea. When the thin film transistor Q is turned on, forward bias voltage between a power source potential Vc and ground is applied to the light emitting diode 10′. When forward bias voltage is applied between the cathode electrode Ec and anode electrode Ea, current flows between the both and electrons from the cathode electrode Ec and holes from the anode electrode Ea flow into the light emitting layer 10b in which the electrons and holes are recombined to emit light. An aromatic amine compound may be used as the hole transport layer 10c and a metal complex type material (tris(8-quinolinolato) aluminum, oxadiazole type material (PBD:

2-(4-Biphenylyl)-5-phenyl-4-t-butylphenyl)-1,3,4-oxadiazole), or triazole type material (TAZ) may be used as the electron injection material 10a. As the light emitting layer 10b, a n-conjugated polymer, pigment-containing polymer, or the like may be used. Here, these materials are not intended to be limiting of this embodiment since there are various materials as the structural material of the light emitting diode 10′.

As explained above, the organic EL display device 10 has a structure in which the linear polarizing plate 5 is disposed on the organic EL panel 1 and the ¼ wavelength plate 3 is disposed between the both. Also, the organic EL display device 100 has a structure in which the linear polarizing plate 5 is disposed on the organic EL panel 1 and the touch sensor panel 14 and ¼ wavelength plate 3 are disposed in this order from the organic EL panel 1 side between the linear polarizing plate 5 and organic EL panel 1.

The material of the organic EL panel 1 is not limited to those disclosed here and conventionally known materials may be applied to the organic EL panel 1. Also, the organic EL panel 1 has a structure in which an anode and a cathode are laminated on a substrate and at least one organic thin film layer is provided between the above cathode and anode. These structures are well known in the technical fields concerned and detailed explanations of them are omitted.

In this case, the anode electrode Ea contains at least one of compounds selected from metal oxides and metal nitrides such as ITO, IZO, IGZO, tin oxides, zinc oxides, zinc-aluminum oxides, and titanium nitrides; metals such as gold, platinum, silver, copper, aluminum, nickel, cobalt, lead, molybdenum, tungsten, tantalum, and niobium; alloys of these metals and alloys of iodine compounds of copper; and conductive polymer materials such as polyaniline, polypyrrole, polyphenylene vinylene, and poly(3-methylthiophene). The anode electrode may be formed from either only one of the above compounds or a mixture of plurality of compounds selected from the above compounds. Also, as the anode electrode, a multilayer structure constituted of a plurality of layers having the same compositions or different compositions may be formed.

As the cathode electrode Ec, materials known in the technical fields concerned may be used without any limitation. The cathode electrode Ec may be used as a cathode of a metal having a low work function such as Al, Ca, Mg, or Ag and preferably Al by using LiF as the electron injection layer.

The organic thin-film layer disposed between the anode electrode Ea and cathode electrode Ec contains the light emitting layer 10b to attain red, green, or blue light emission and, in addition, at least one of a hole injection layer, hole transport layer, electron injection layer, and electron transport layer. For example, the organic thin-film layer may have a laminate structure consisting of an anode electrode, hole injection layer, hole transport layer, light emitting layer, electron transport layer, electron injection layer, and a cathode electrode.

The above light emitting layer 10b may use a dopant material besides the host materials that are major materials. These materials are not intended to be limiting of the present invention because various kinds of material are known as the host material and dopant material. Also, the above various layers are not intended to be limiting of the present invention, because various kinds of hole injection layers, hole transport layers, electron transport layers, and electron injection layers are known.

There are a passive (PM) type and an active (AM) type as a driving system of the organic EL display panel 1 and any of these types may be applied.

As the materials of the anode electrode Ea and cathode electrode Ec, metals such as gold, silver, copper, and aluminum may be used. When, for example, aluminum is used as the anode electrode Ea, the anode electrode Ea functions as a mirror that reflects external light. This is the same for the cathode electrode Ec. The reflectance Rp (%) of the front surface of the organic EL display panel 1 differs depending on the materials and structures of the anode electrode Ea and cathode electrode Ec and is preferably, for example, 30 to 70%. Here, the reflectance Rp (%) is a value measured in an SCI mode by using a spectrophotometer (CM-2600d, manufactured by KONICA MINOLTA, INC.).

It is considered that when an optical laminate provided with a reflector which has a metal film such as an aluminum film on the surface thereof is used in place of the organic EL display panel 1 illustrated in FIGS. 1 and 2, almost the same behavior as in an organic EL display device is shown concerning the reflection of external light by investigating the optical characteristics of the optical laminate. Accordingly, the inventors of the present application manufactured such an optical laminate for verification to make earnest studies on optical characteristics and have completed the present invention.

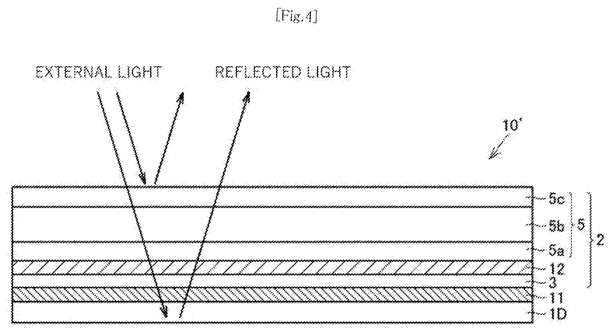

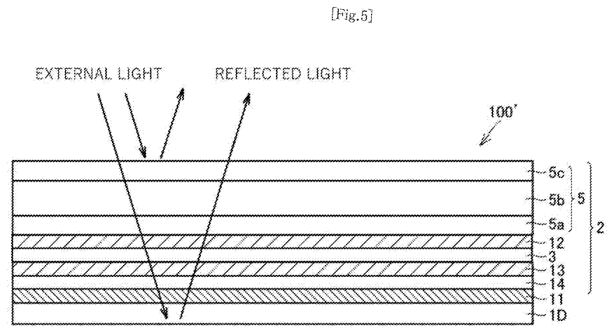

FIGS. 4 and 5 are vertical sectional views of a sample of the optical laminate for verification. The optical laminates 10′ and 100′ for verification are provided with a reflector 1D in place of an image display panel. The reflector 1D is provided in place of the organic EL display panel 1 in the organic EL display devices 10 and 100 of FIGS. 1 and 2 and is hypothetically handled as a reflective element (for example, the anode electrode Ea and cathode electrode Ec) in the organic EL display device.

### EXAMPLES

The present invention will be explained in more detail by way of examples.

### Test Examples 1 to 18

Optical laminates for verification as shown in FIG. 4 were constituted as Test Examples 1 to 13 to measure the reflectance Rd (%) of the front surface of each optical laminate. The results of measurement are shown in Table 1. Also, optical laminates for verification as shown in FIG. 5 were constituted as Test Examples 14 to 18 to measure the reflectance Rd (%) of the front surface of each optical laminate. The results of measurement are shown in Table 2. Here, the reflectance Rd (%) is a value measured in an SCI mode by using a spectrophotometer (CM-2600d, manufactured by KONICA MINOLTA, INC.). Also, with regards to Test Examples 14 to 18, the visibility of the touch sensor pattern was evaluated according to the following standard and the results are shown in Table 2.

A: The touch sensor pattern cannot be viewed from the viewing side;

B: The touch sensor pattern can be slightly viewed from the viewing side; and

C: The touch sensor pattern can be viewed from the viewing side.

The reflector 1D and antireflective polarizing plate constituting the optical laminate for verification which was used in each test example are as follows.

### <Reflector>

In Test Examples 1 to 18, the reflectors shown in Tables 1 and 2 among the following four kinds of reflectors were used as the reflector 1D shown in FIGS. 4 and 5. With regards to each reflector, the reflectance of the front surface was measured in an SCI mode by using a spectrophotometer (CM-2600d, manufactured by KONICA MINOLTA, INC.) and the measured value was defined as the reflectance Rp (%).

### (Reflector 1: Mirror)

A commercially available mirror was cut into a size of 100 mm×100 mm and the cut mirror was named as a reflector 1. The reflectance Rp (%) of the front surface of the reflector 1 was 93.70%.

### (Reflector 2: Glass Substrate to Which an Aluminum Foil is Pasted)

A commercially available aluminum foil was cut into a size of 100=×100 mm which was then pasted to a commercially available glass substrate by using a pressure-sensitive adhesive to make a reflector 2. The substrate surface to which no aluminum foil was pasted was named as the front surface of the reflector 2 to measure the reflectance Rp (%) of the front surface of the reflector 2, to find that the Rp was 79.28%.

(Reflector 3: Glass Substrate to Which an Aluminum Foil is Pasted and, Which is Provided With a Printing Layer)

A network pattern was printed on one surface of a commercially available glass substrate by using black ink. In the network pattern, the width of each line constituting the network pattern was 100 μm and the interval between lines was 500 μm. A commercially available aluminum foil was cut into a size of 100 mm×100 mm which was then pasted to the glass substrate surface on which no printing layer was formed by using a pressure-sensitive adhesive to make a reflector 3. The glass substrate surface to which no aluminum foil was pasted was named as the front surface of the reflector 3 to measure the reflectance Rp (%) of the front surface of the reflector 3, to find that the Rp was 58.61%.

### (Reflector 4: Glass Substrate to Which an Aluminum Foil is Pasted, and Which is Provided With a Printing Layer)

A network pattern was printed on one surface of a commercially available glass substrate by using black ink. In the network pattern, the width of each line constituting the network pattern was 300 μm and the interval between lines was 300 μm. A commercially available aluminum foil was cut into a size of 100 mm×100 mm which was then pasted to the glass substrate surface on which no printing layer was formed by using a pressure-sensitive adhesive to make a reflector 4. The glass substrate surface to which no aluminum foil was pasted was named as the front surface of the reflector 4 to measure the reflectance Rp (%) of the front surface of the reflector 4, to find that the Rp was 17.00%.

### <Antireflective Polarizing Plate>

In Test Examples 1 to 13, an antireflective polarizing plate on which a linear polarizing plate and ¼ wavelength plate were laminated in this order from the viewing side was used as the antireflective polarizing plate 2. Also, in Test Examples 14 to 18, an antireflective polarizing plate on which a linear polarizing plate, ¼ wavelength plate, and touch sensor panel were laminated in this order from the viewing side was used as the antireflective polarizing plate 20. As the linear polarizing plate, the linear polarizing plate shown in Tables 1 and 2 was used among a PVA polarizing plate 1, PVA polarizing plate 2, and liquid crystal type polarizing plate for which each production method was shown below. A ¼ wavelength plate for which a production method was shown below was used as the ¼ wavelength plate in all test examples. As the touch sensor panel, a touch sensor panel shown in Table 2 was used among a touch sensor panel with a base material layer and touch sensor panel with no base material layer for which each production method was shown below. The antireflective polarizing plate was produced by the following production method. The antireflective polarizing plate used in each test example was measured using a spectrophotometer (V7100, manufactured by JASCO Corporation) to calculate Ty, Tcr, and Py by the method mentioned above. The results of calculation are shown in Tables 1 and 2.

### (PVA Polarizing Plate 1)

Orientation treatment, iodine dying treatment, boron crosslinking treatment, and drying treatment was treated on a PVA film to make a polarizing film and a TAC film was laminated on one surface of the obtained polarizing plate by using an adhesive to obtain a PVA polarizing plate 1.

### (PVA Polarizing Plate 2)

A PVA polarizing plate 2 was obtained in the same method as the PVA polarizing plate 1 except that the PVA film treating condition was changed.

### (Liquid Crystal Type Polarizing Plate)

An orientation membrane composition was applied to one surface of a TAC film, followed by drying and exposing to polarized light to form an orientation membrane. A liquid crystal composition containing a liquid crystal polymerizable compound and a dye was applied to the surface of the orientation membrane, which was then cured by irradiation with UV light after dried, to form a polarizing layer, thereby producing a liquid crystal type polarizing plate. Ty, Py, and Tcr of each liquid crystal type polarizing plate were controlled to the values shown in Table 1 by adjusting the amount of the dye to be added to the liquid crystal composition.

### (¼ Wavelength Plate)

An orientation membrane composition was applied to one surface of a PET film, followed by drying and exposing to polarized light to form an orientation membrane. A liquid crystal composition containing a liquid crystal polymerizable compound was applied to the orientation membrane, which was then cured by irradiation with UV light after dried to form a retardation layer, thereby producing a ¼ wavelength plate with a PET film. A laminate consisting of an orientation membrane and retardation layer was obtained as a ¼ wavelength plate.

### (Touch Sensor Panel With a Base Material Layer)

As the touch sensor panel with a base material layer, a structure provided with a touch sensor pattern layer, adhesive layer, and a base material layer which were laminated in this order was prepared. The touch sensor pattern layer contained an ITO layer as a transparent conductive layer and a cured layer of an acrylic resin composition as a release layer and had a thickness of 7 μm. The adhesive layer was disposed on the release layer side of the touch sensor pattern layer and had a thickness of 3 μm.

### (Touch Sensor Panel With No Base Material Layer)

A touch sensor panel consisting only of a touch sensor pattern layer was prepared as the touch sensor panel with no base material layer. The touch sensor pattern layer contained an ITO layer as a transparent conductive layer and a cured layer of an acrylic resin composition as a release layer and had a thickness of 7 μm.

### (Antireflective Polarizing Plate)

The surface of the ¼ wavelength plate on which surface no TAC film was formed was pasted to the surface of the linear polarizing plate on which surface no PET film was formed, by using a pressure-sensitive adhesive and then, the PET film was peeled off to thereby obtain an antireflective polarizing plate consisting of a linear polarizing plate and ¼ wavelength plate. Also, a touch sensor panel was pasted to the ¼ wavelength plate side through a pressure-sensitive adhesive to thereby obtain an antireflective polarizing plate consisting of a linear polarizing plate, ¼ wavelength plate, and touch sensor panel. When a touch sensor panel with a base material layer was used as the touch sensor panel, the touch sensor panel was pasted such that the touch sensor pattern layer side was positioned on the ¼ wavelength plate side.

### (Optical Laminate for Verification)

In each test example, each antireflective polarizing plate shown in Tables 1 and 2 was pasted to the front surface of each corresponding reflector by using a pressure-sensitive adhesive to obtain optical laminates for verification as shown in FIGS. 4 and 5. The antireflective polarizing plate was pasted to each reflector such that the linear polarizing plate was disposed on the viewing side.

TABLE 1

| | | | Antireflective polarizing plate | | | | | | |
|---|---|---|---|---|---|---|---|---|---|
| | | | (linear polarizing plate + | | | | | | Optical |
| | Reflector | | ¼ wavelength plate) | | | | | | laminate |
| | | Rp | Type of Linear | Ty | Tcr | Py | | Rp × Tcr × | Rd |
| | Type | (%) | polarizing plate | (%) | (%) | (%) | Rp × Tcr | Py × 10⁻² | (%) |
| Test Example 1 | Reflector 1 | 93.70 | PVA polarizing plate 1 | 44.48 | 0.33 | 99.16 | 31.13 | 30.87 | 4.58 |
| Test Example 2 | Reflector 2 | 79.28 | PVA polarizing plate 1 | 44.48 | 0.33 | 99.16 | 26.34 | 26.12 | 4.51 |
| Test Example 3 | Reflector 2 | 79.28 | PVA polarizing plate 2 | 44.72 | 0.69 | 98.25 | 54.77 | 53.82 | 4.97 |
| Test Example 4 | Reflector 3 | 58.61 | Liquid crystal type | 41.70 | 0.91 | 97.35 | 53.27 | 51.86 | 4.25 |
| | | | polarizing plate | | | | | | |
| Test Example 5 | Reflector 3 | 58.61 | Liquid crystal type | 41.74 | 1.06 | 96.91 | 62.28 | 60.36 | 4.57 |
| | | | polarizing plate | | | | | | |
| Test Example 6 | Reflector 4 | 17.00 | Liquid crystal type | 42.63 | 1.26 | 96.48 | 21.45 | 20.70 | 4.40 |
| | | | polarizing plate | | | | | | |
| Test Example 7 | Reflector 1 | 93.70 | Liquid crystal type | 41.70 | 0.91 | 97.37 | 85.27 | 83.02 | 5.73 |
| | | | polarizing plate | | | | | | |
| Test Example 8 | Reflector 2 | 79.28 | Liquid crystal type | 41.70 | 0.91 | 97.37 | 72.15 | 70.25 | 5.56 |
| | | | polarizing plate | | | | | | |
| Test Example 9 | Reflector 2 | 79.28 | Liquid crystal type | 42.21 | 1.06 | 97.00 | 84.05 | 81.52 | 5.98 |
| | | | polarizing plate | | | | | | |
| Test Example 10 | Reflector 2 | 79.28 | Liquid crystal type | 42.04 | 1.19 | 96.60 | 94.23 | 91.02 | 6.02 |
| | | | polarizing plate | | | | | | |
| Test Example 11 | Reflector 3 | 58.61 | Liquid crystal type | 42.46 | 1.55 | 95.61 | 90.79 | 86.81 | 5.39 |
| | | | polarizing plate | | | | | | |
| Test Example 12 | Reflector 3 | 58.61 | Liquid crystal type | 44.22 | 2.93 | 92.24 | 171.76 | 158.43 | 6.66 |
| | | | polarizing plate | | | | | | |
| Test Example 13 | Reflector 4 | 17.00 | Liquid crystal type | 51.39 | 13.47 | 70.13 | 228.94 | 160.56 | 6.20 |
| | | | polarizing plate | | | | | | |

As is clear from the value of Rd (%) of the optical laminate shown in Table 1, Test Examples 1 to 6 which each have a Rp×Tcr value of 68 or less and satisfy the relations of the formulae (1a) and (1b) have a reflectance Rd (%) as low as 5.0% or less, showing that each test example has an excellent effect of restraining visibility deterioration caused by reflected light. Test Examples 7 to 11 which each have a Rp×Tcr value of 150 or less and satisfy the relation of the formula (1a) have a reflectance Rd (%) as low as 6.1% or less, showing that each test example has an excellent effect of restraining visibility deterioration caused by reflected light.

TABLE 2

| | | | Antireflective polarizing plate (linear polarizing plate + | | | | | | | Optical | Visibility |
|---|---|---|---|---|---|---|---|---|---|---|---|
| | Reflector | | ¼ wavelength plate + touch sensor panel) | | | | | | | laminate | of Touch |
| | | Rp | Type of Linear | Type of touch sensor | Ty | Tcr | Py | Rp × | Rp × Tcr × | Rd | sensor |
| | Type | (%) | polarizing plate | panel | (%) | (%) | (%) | Tcr | Py × 10⁻² | (%) | pattern |
| Test | Reflector | 58.61 | Liquid crystal type | Touch sensor panel with | 41.69 | 0.89 | 97.31 | 52.16 | 50.8 | 4.25 | A |
| Example 14 | 3 | | polarizing plate | Base material layer | | | | | | | |
| Test | Reflector | 58.61 | Liquid crystal type | Touch sensor panel with | 41.74 | 1.12 | 97.50 | 65.64 | 64.0 | 5.20 | A |
| Example 15 | 3 | | polarizing plate | Base material layer | | | | | | | |
| Test | Reflector | 79.28 | Liquid crystal type | Touch sensor panel with | 41.70 | 0.92 | 97.29 | 72.94 | 69.4 | 5.60 | B |
| Example 16 | 2 | | polarizing plate | Base material layer | | | | | | | |
| Test | Reflector | 79.28 | Liquid crystal type | Touch sensor panel with | 42.21 | 1.12 | 97.00 | 88.79 | 77.7 | 6.00 | B |
| Example 17 | 2 | | polarizing plate | Base material layer | | | | | | | |
| Test | Reflector | 17.00 | Liquid crystal type | Touch sensor panel with | 55.01 | 16.04 | 61.14 | 324 | 198.1 | 6.70 | C |
| Example 18 | 4 | | polarizing plate | Base material layer | | | | | | | |

As is clear from the value of Rd (o) of the optical laminate shown in Table 2, Test Examples 14 to 17 which each have a Rp×Tcr value of 100 or less and satisfy the relations of the formulae (1a) and (1d) have a reflectance Rd (%) as low as 6.0% or less, showing that each test example has an excellent effect of restraining visibility deterioration caused by reflected light and also, the touch sensor pattern is scarcely visible.

1. An antireflective polarizing plate disposed on a front surface of an image display panel having a front-surface reflectance of Rp (%),
the antireflective polarizing plate having a luminosity corrected cross transmittance Tcr (%) satisfying a relation expressed by the formula (1a):
Rp×Tcr≤150 (1a)

2. The antireflective polarizing plate according to claim 1,
the antireflective polarizing plate comprising a touch sensor panel, a retardation plate, and a linear polarizing plate in this order,
being disposed on the front surface of the image display panel such that the touch sensor panel faces the image display panel, and
having a luminosity corrected cross transmittance Tcr (%) satisfying a relation expressed by the formula (1d):
Rp×Tcr≤100 (1d)

3. The antireflective polarizing plate according to claim 1,
the antireflective polarizing plate having a luminosity corrected cross transmittance Tcr (%) satisfying a relation expressed by the formula (1b):
Rp×Tcr≤68 (1b)

4. The antireflective polarizing plate according to claim 1,
the antireflective polarizing plate having a luminosity corrected degree of polarization Py (%) of 95% or more.

5. The antireflective polarizing plate according to claim 1,
the antireflective polarizing plate further comprising a polarizing layer containing a polymer of a polymerizable liquid crystal compound.

6. An optical laminate comprising an image display panel and the antireflective polarizing plate according to claim 1, the antireflective polarizing plate being disposed on the front surface of the image display panel.

7. The optical laminate according to claim 6, the optical laminate being an organic EL display device.

8. A method for producing an optical laminate, the method comprising:
a step of preparing an image display panel having a front-surface reflectance of Rp (%);
a step of preparing an antireflective polarizing plate having a luminosity corrected cross transmittance Tcr (%) satisfying a relation expressed by the formula (1a); and
a step of disposing the antireflective polarizing plate on a front surface of the image display panel:
Rp×Tcr≤150 (1a)
